(19) United States
(12) Patent Application Publication
(10) Pub. No.: US 2017/0126177 A1
(43) Pub. Date: May 4, 2017

(54) Trifilar Voltage Controlled Oscillator

(71) Applicant: Texas Instruments Incorporated, Dallas, TX (US)

(72) Inventors: Sachin Kalia, Minneapolis, MN (US); Bradley A. Kramer, Plano, TX (US); Swaminathan Sankaran, Allen, TX (US)

(73) Assignee: Texas Instruments Incorporated, Dallas, TX (US)

(21) Appl. No.: 14/928,268

(22) Filed: Oct. 30, 2015

(51) Int. Cl. H03B 5/12

(52) U.S. Cl. CPC H03B 5/1212; H03B 5/124

(57) ABSTRACT

A voltage controlled oscillator (VCO) for providing an oscillating output signal. The VCO includes a first inductor, and the oscillating output signal is responsive to a changing current through the first inductor. The VCO also includes a second inductor, proximate the first inductor, coupled to a first cross-coupling stage and a third inductor, proximate the first inductor, coupled to a second cross-coupling stage.

### CROSS-REFERENCES TO RELATED APPLICATIONS

Not Applicable.

### STATEMENT REGARDING FEDERALLY SPONSORED RESEARCH OR DEVELOPMENT

Not Applicable.

### BACKGROUND OF THE INVENTION

The preferred embodiments relate to voltage controlled oscillator (VCO) technology and, more particularly, to a VCO with a trifilar inductive coil.

A VCO is a device (i.e., oscillator) that outputs an oscillating signal with a frequency that is controlled by the level of an input voltage applied to the VCO. A fixed DC input voltage to the VCO, therefore, should ideally produce a fixed output frequency signal, whereas that input voltage also may be varied so as to vary the VCO output frequency. As to the latter, therefore, a modulating input signal may be applied to cause the VCO to output a signal with a modulating frequency (or phase).

By way of further background, FIG. 1 illustrates a schematic of a prior art VCO shown generally at 10. VCO 10 includes bias control circuitry 12 that may be constructed according to known principles for biasing VCO 10, as further explored below. One connection from bias control circuitry 12 is to a gate of a first nMOS transistor 14, which has its source connected to ground. The drain of first nMOS transistor 14 is connected to a source of a second nMOS transistor 16 and to a source of a third nMOS transistor 18.

VCO 10 also includes a transformer 20, shown in a dashed box and including a first inductor I1 and a second inductor I2, where polarities as between inductors I1 and I2 are shown according to the well-known dot convention. A first terminal T1_{I1} of inductor I1 is connected to the drain of nMOS transistor 16, a second terminal T2_{I1} of inductor I1 is connected to the drain of nMOS transistor 18, and a center tap of inductor I1 is connected to a fixed voltage potential, shown as V_{DD}. A first terminal T1_{I2} of inductor I2 is connected to the gate third of nMOS transistor 18, a second terminal T2_{I2} of inductor I2 is connected to the gate of second nMOS transistor 16, and a center tap of inductor I2 is connected to bias control circuitry 18. The oscillator output signal, νₒᵤₜ, is provided as a differential signal between the respective drains of second nMOS transistor 16 and third nMOS transistor 18.

The operation of VCO 10 is well understood to one skilled in the art and, therefore, is only generally addressed herein. In general, VCO 10 provides a frequency response in νₒᵤₜ based on the inductance and parasitic capacitance of transformer 20, the parasitic capacitance of nMOS transistors 16 and 18, as well as the bias voltages from bias control circuitry 12, which further control a contribution to νₒᵤₜ based on the biasing of nMOS transistor 14. Thus, energy oscillates between the inductance and capacitance, giving rise to the oscillating output νₒᵤₜ. Note that resistance also exists in the circuit which itself would tend to diminish the response of the circuit, but as known in the VCO art there is designed into VCO 10 a negative conductance, sometimes also referred to as a −R, so as to compensate for this resistance. In VCO 10, the negative conductance is achieved via the positive feedback provided by the cross-coupled configuration of nMOS transistors 16 and 18, relative to inductor I2. More specifically, the inductance of inductor I1 combines with capacitance to provide a resonating output while also inducing a signal into inductor I2, which is cross-coupled and thereby provides in-phase positive feedback to the gates of nMOS transistors 16 and 18, thereby sustaining νₒᵤₜ.

While the above and related approaches have served various needs in the prior art, they also provide various drawbacks. For example, when VCO 10 is implemented in an (e.g., silicon) integrated circuit, the transformer inductors are typically constructed using different layers of the back end metal process. For the two inductor transformer, therefore, typically each inductor is built in a separate metal layer, thereby consuming a considerable amount of two-dimensional area, where area in itself can be a critical design consideration for numerous devices and applications. Moreover, various performance measures are desirable, having dedicated such transformer area for the VCO. A first and key such measure is power consumed. A second measure is phase noise, which is a figure of merit on accuracy of νₒᵤₜ frequency for a given bias voltage, where such accuracy also includes susceptibility to jitter around the intended frequency tone at a given bias voltage.

Given the preceding, the present inventors seek to improve upon the prior art, as further detailed below.

### BRIEF SUMMARY OF THE INVENTION

In a preferred embodiment, there is a voltage controlled oscillator (VCO) for providing an oscillating output signal. The VCO includes a first inductor, and the oscillating output signal is responsive to a changing current through the first inductor. The VCO also includes a second inductor, proximate the first inductor, coupled to a first cross-coupling stage and a third inductor, proximate the first inductor, coupled to a second cross-coupling stage.

Numerous other inventive aspects are also disclosed and claimed.

### BRIEF DESCRIPTION OF THE SEVERAL VIEWS OF THE DRAWING

FIG. 1 illustrates an electrical schematic of a prior art voltage controlled oscillator.

FIG. 2 illustrates an electrical schematic of a voltage controlled oscillator according to a preferred embodiment.

FIG. 3A illustrates an exploded perspective view of three inductors included in a preferred embodiment voltage controlled oscillator.

FIG. 3B illustrates a cross-sectional view of three inductors included in a preferred embodiment voltage controlled oscillator.

FIG. 4 again illustrates the VCO of FIG. 2, with a few additional illustrated aspects.

### DETAILED DESCRIPTION OF EMBODIMENTS

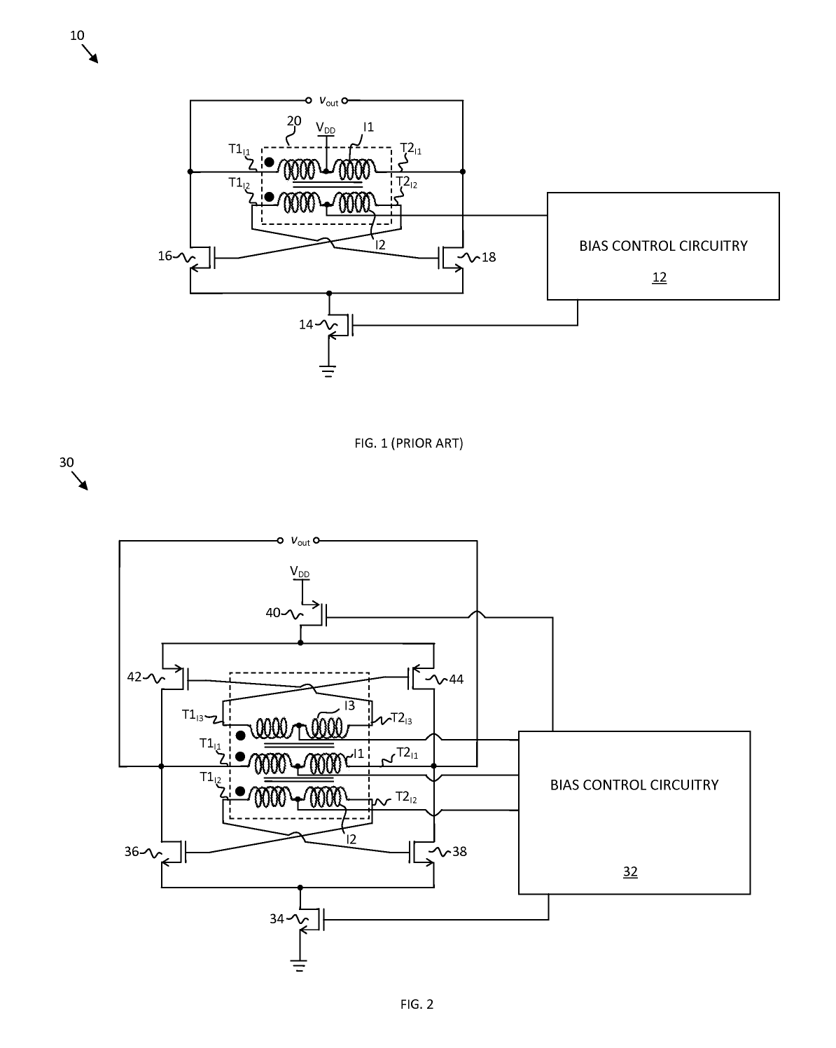

FIG. 1 was described above in the Background of the Invention section of this document, and the reader is assumed familiar with the principles of that discussion.

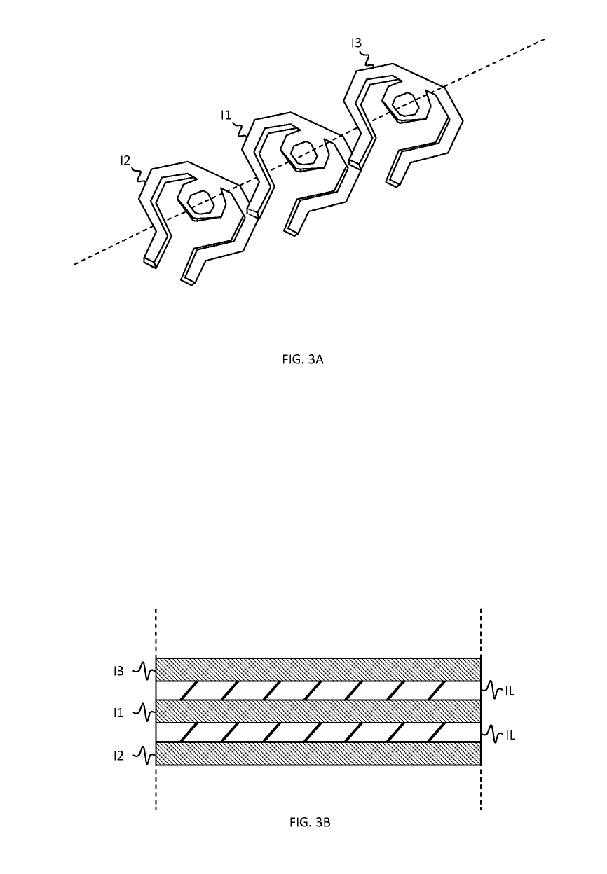

FIG. 2 illustrates a schematic of a preferred embodiment voltage controlled oscillator (VCO) shown generally at 30. VCO 30 includes bias control circuitry 32 that may be constructed according to known principles for biasing a VCO and more particularly for biasing VCO 30, as further explored below. One connection from bias control circuitry 32 is to a gate of a first nMOS transistor 34, which has its source connected to a reference potential, such as ground. The drain of first nMOS transistor 34 is connected to a source of a second nMOS transistor 36 and to a source of a third nMOS transistor 38. Another connection from bias control circuitry 32 is to a gate of a first pMOS transistor 40, which has its source connected to a fixed supply voltage, designated V_{DD}. The drain of first pMOS transistor 40 is connected to a source of a second pMOS transistor 42 and to a source of a third pMOS transistor 44.

VCO 30 also includes a trifilar transformer 30, meaning a transformer with three different inductor coils as shown in a dashed box and including a first inductor I1, a second inductor I2, and a third inductor I3, where polarities as between inductors I1, I2, and I3 are shown according to the well-known dot convention. A first terminal T1_{I1} of inductor I1 is connected to the drain of second nMOS transistor 36, a second terminal T2_{I1} of inductor I1 is connected to the drain of third nMOS transistor 38, and a center tap (or alternatively some other intermediate point between its terminals) of inductor I1 is connected to bias control circuitry 32. A first terminal T1_{I2} of inductor I2 is connected to the gate of third nMOS transistor 38, a second terminal T2_{I2} of inductor I2 is connected to the gate of second nMOS transistor 36, and a center tap (or alternatively some other intermediate point between its terminals) of inductor I2 is connected to bias control circuitry 32. A first terminal T1_{I3} of inductor I3 is connected to the gate of third pMOS transistor 44, a second terminal T2_{I3} of inductor I3 is connected to the gate of second pMOS transistor 42, and a center tap (or alternatively some other intermediate point between its terminals) of inductor I3 is connected to bias control circuitry 32. The drain of second pMOS transistor 42 is connected to the drain of second nMOS transistor 36 and also to terminal T1_{I1}. The drain of third pMOS transistor 44 is connected to the drain of third nMOS transistor 38 and also to terminal T2_{I1}. The oscillator output signal, νₒᵤₜ is provided as a differential signal between terminal T1_{I1} (i.e., the same nodes as the drains of second nMOS transistor 36 and second pMOS transistor 42) and terminal T2_{I1} (i.e., the same nodes as the drains of third nMOS transistor 38 and third pMOS transistor 44).

The operation of VCO 30 should be appreciated by one skilled in the art and is further addressed here. In general, VCO 30 provides a frequency response in νₒᵤₜ based on the inductance and parasitic of transformer 30, the parasitic capacitance of nMOS transistors 36 and 38 and pMOS transistors 42 and 44, as well as the bias voltages from bias control circuitry 32, which further control a contribution to νₒᵤₜ based on the biasing of first nMOS transistor 34 and the biasing of first pMOS transistor 40. In an alternative preferred embodiment, explicit capacitance through discrete devices also could be added, thereby further influencing the characteristics of νₒᵤₜ. In all events, therefore, energy oscillates between the trifilar inductance and capacitance, giving rise to the oscillating output, and a negative cross-conductance is achieved through two different cross-coupled configurations, one with respect to inductor I2 and another with respect to inductor I3.

Given the preceding, the preferred embodiment VCO 30 provides numerous advantages over the prior art.

One preferred embodiment benefit of VCO 30 is that the power required to achieve an oscillating output of νₒᵤₜ is reduced relative to the prior art, possibly by a factor greater than two. For example, the preferred embodiment includes two cross-coupling stages, shown by way of preferred example as an nMOS cross-coupling with nMOS transistors 36 and 38 and a pMOS cross-coupling with pMOS transistors 42 and 44. These stages thereby double the net get as compared to the FIG. 1 prior art. In addition, depending on implementation, a gain may be achieved between multiple coil pairs; for instance, consider inductor I1 as a primary coil, it can induces a voltage (or current) boost into one or both of inductors I2 and I3, such as via the relative amount of turns as between the pair of inductors I1 and I2 or I1 and I3. Such additional magnetic boosting can further reduce DC power requirements to VCO 30.

Another preferred embodiment benefit of VCO 30 is that separate biasing is available for both the nMOS transistor 34 to ground and the pMOS transistor 40 to V_{DD}. In this respect, the sensitivity of each to noise can be separately or independently suppressed, via the respective gate potentials of nMOS transistor 34 and pMOS transistor 40. Indeed, this benefit has an additional potential benefit to relax standards of the voltage supply to VCO 30. Specifically, often in the art a low drop out (LDO) supply is used for V_{DD} and strict and cost-influencing requirements are placed on the LDO supply so as to allow it to suppress noise. The preferred embodiment's ability to separately suppress noise, therefore, permits the requirements on such an LDO to be reduced, thereby improving cost and efficiency considerations.

Another preferred embodiment benefit of VCO 30 is that separate biasing is available for the center tap of all inductors I1, I2, and I3. Again, therefore, noise influence associated with one device can be separated from noise influence associated with the other. Moreover, the preferred embodiment provides an improvement in gate swing, one for the PMOS side and one for the NMOS side.

FIG. 3A illustrates a perspective exploded view, and FIG. 3B a side cross-sectional view, of a configuration in which each of inductors I1, I2 and I3 may be formed in connection with well-known semiconductor and integrated circuit fabrication processes. In this preferred embodiment, each inductor is generally a same shape and may be formed so that a majority of the metal for the inductor is positioned in a different respective metal layer in a semiconductor process. As shown in the exploded view of FIG. 3A, therefore, in the metal layers of a semiconductor process, inductor I2 would be formed from metal, below the formation of a metal inductor I1, and inductor I3 would be formed from metal, above inductor I1; this is also shown by way of cross-section in FIG. 3B, where intermediate (e.g., insulating) layers IL are formed between the inductors, for simplification. Given the shape and orientation in FIGS. 3A and 3B, note that two dimensions (e.g., from a top-down view), therefore, the shape and borders of inductors I1, I2 and I3 are vertically aligned, so that the area consumed by the trifilar device in those two dimensions is no greater than for a prior art two-inductor device. This gives rise to another preferred embodiment benefit in that typically inductors consume a considerable amount of two-dimensional area, particularly relative to the rest of the circuitry required to implement a VCO (and related circuitry). The preferred embodiment FIG. 2 schematic may be achieved via FIGS. 3A and 3B with its additional inductor formed in a same two-dimensional space, by aligning it in the third dimension (e.g., vertically) in line with the other inductors. As such, the various benefits described above are achieved without a two-dimensional increase in surface area.

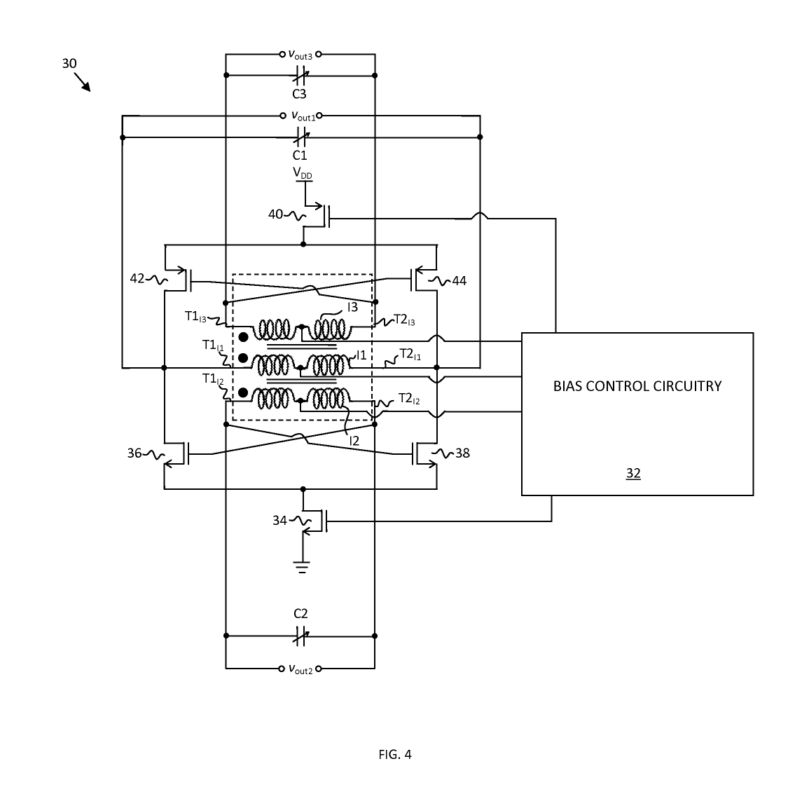

FIG. 4 again illustrates VCO 30 of FIG. 2, with a few additional illustrated aspects. Specifically, as a trifilar coil VCO, also contemplated in preferred embodiments is that an output of VCO 30 can be tapped from the respective differential signal across any of the three inductors I1, I2, and I3. Thus, in FIG. 4, respective outputs νₒᵤₜ₁, νₒᵤₜ₂, and νₒᵤₜ₃ are shown in this regard. In addition, across each such output is a respective tuning (i.e., variable) capacitor, C1, C2, and C3. In a preferred embodiment, each such capacitor is a combination of switched capacitors (for band tuning) and varactors (for continuous tuning). As an alternative, any of capacitors C1, C2 or C3 may be replaced with an explicit switched capacitor plus a MOS varactor in parallel. Moreover, all of capacitors C1, C2 or C3 need not have continuous (or analog) tuning, and each can be scaled differential and can have different bit sizes and the like, depending on the frequency of oscillation and whether multiple oscillation modes are present. Thus, VCO 30 can have multiple oscillation modes and selection of one (and suppression of the rest) also will factor in the choice and tuning on capacitors C1, C2, and C3.

From the above, the preferred embodiments are shown to provide a VCO with a trifilar inductive transformer with plural cross-coupling stages so as to improve numerous metrics as compared to the prior art. In one preferred embodiment, a first cross-coupling stage is formed by nMOS transistors with respect to one inductor of the trifilar transformer, while a second cross-coupling stage is formed by pMOS transistors with respect to another inductor of the trifilar transformer. Separate biasing devices (e.g., transistors) are also contemplated in a preferred embodiment for respective ones of the cross-coupled stages and respective inductor center taps. The preferred embodiment construction may use area comparable in two dimensions to that used by a prior art configuration, while considerably outperforming that prior art configuration. Thus, the preferred embodiments are demonstrated to have numerous benefits, and still others will be further determined by one skilled in the art. Moreover, while various embodiments have been provided, one skilled in the art may adjust various measures and architectures according to application and other considerations. For example, while FIGS. 3A and 3B show the each inductor in the trifilar transformer in a separate metal layer, in an alternative preferred embodiment two or more inductors may be formed in the same layer, with connections thereto potentially extending to other metal layers. Still further, while various alternatives have been provided according to the disclosed embodiments, still others are contemplated and yet others can ascertained by one skilled in the art. Given the preceding, therefore, one skilled in the art should further appreciate that while some embodiments have been described in detail, various substitutions, modifications or alterations can be made to the descriptions set forth above without departing from the inventive scope, as is defined by the following claims.

1. A voltage controlled oscillator for providing an oscillating output signal, comprising:
a first inductor, wherein the oscillating output signal is responsive to a changing current through the first inductor;
a second inductor, proximate the first inductor, electrically connected to a first cross-coupling stage; and
a third inductor, proximate the first inductor, electrically connected to a second cross-coupling stage.

2. The voltage controlled oscillator of claim 1:
wherein the first cross-coupling stage comprises a plurality of nMOS transistors; and
wherein the second cross-coupling stage comprises a plurality of pMOS transistors.

3. The voltage controlled oscillator of claim 1 wherein the first cross-coupling stage comprises:
a first nMOS transistor having a gate connected to a first terminal of the second inductor; and
a second nMOS transistor having a gate connected to a second terminal of the second inductor.

4. The voltage controlled oscillator of claim 3 and further comprising a third nMOS transistor having a drain coupled to a source of the first nMOS transistor and to a source of the second nMOS transistor.

5. The voltage controlled oscillator of claim 4 and further comprising biasing circuitry coupled to a gate of the third nMOS transistor for applying a gate bias.

6. The voltage controlled oscillator of claim 1 wherein the second cross-coupling stage comprises:
a first pMOS transistor having a gate connected to a first terminal of the third inductor; and
a second pMOS transistor having a gate connected to a second terminal of the third inductor.

7. The voltage controlled oscillator of claim 6 and further comprising a third pMOS transistor having a drain coupled to a source of the first pMOS transistor and to a source of the second pMOS transistor.

8. The voltage controlled oscillator of claim 7 and further comprising biasing circuitry coupled to a gate of the third pMOS transistor for applying a gate bias.

9. The voltage controlled oscillator of claim 1:
wherein the first cross-coupling stage comprises:
a first nMOS transistor having a gate connected to a first terminal of the second inductor; and
a second nMOS transistor having a gate connected to a second terminal of the second inductor; and
wherein the second cross-coupling stage comprises:
a first pMOS transistor having a gate connected to a first terminal of the third inductor; and
a second pMOS transistor having a gate connected to a second terminal of the third inductor.

10. The voltage controlled oscillator of claim 9 and further comprising:
a third nMOS transistor having a drain coupled to a source of the first nMOS transistor and to a source of the second nMOS transistor;
a third pMOS transistor having a drain coupled to a source of the first pMOS transistor and to a source of the second pMOS transistor; and
biasing circuitry coupled to a gate of the third nMOS transistor and to a gate of the third pMOS transistor for applying a respective gate bias.

11. The voltage controlled oscillator of claim 1 and further comprising biasing circuitry coupled to an intermediate tap between a first tap and a second tap of at least one of the first inductor, the second inductor, and the third inductor, for applying a tap bias to adjust a frequency of the oscillating output signal.

12. The voltage controlled oscillator of claim 1 and further comprising biasing circuitry coupled to a first intermediate tap between a first and second tap of the first inductor, and coupled to a second intermediate tap between a first and second tap of the second inductor, and coupled to a third intermediate tap between a first and second tap of the third inductor, wherein the oscillating output signal has a frequency responsive at least in part to a bias applied by the biasing circuitry coupled to the first intermediate tap, the second intermediate tap, and the third intermediate tap.

13. The voltage controlled oscillator of claim 1 wherein each of the first inductor, the second inductor, and the third inductor has a comparable shape.

14. The voltage controlled oscillator of claim 1 wherein a majority of structure forming each of the first inductor, the second inductor, and the third inductor is formed in a different respective metal layer of an integrated circuit.

15. The voltage controlled oscillator of claim 1 wherein each of the first inductor, the second inductor, and the third inductor is formed in metal of an integrated circuit.

16-23. (canceled)

24. A voltage controlled oscillator for providing an oscillating output signal, comprising:
a first inductor, wherein the oscillating output signal is responsive to a changing current through the first inductor;
a second inductor, proximate the first inductor, electrically connected to a first cross-coupling stage having a plurality of nMOS transistors;
a third inductor, proximate the first inductor, electrically connected to a second cross-coupling stage having a plurality of pMOS transistors;
a biasing circuitry coupled to an intermediate tap between a first tap and a second tap of at least one of the first inductor, the second inductor, and the third inductor to bias the first, second, and third inductors separately.

25. The voltage controlled oscillator of claim 24 wherein the first cross-coupling stage comprises:
a first nMOS transistor having a gate connected to a first terminal of the second inductor; and
a second nMOS transistor having a gate connected to a second terminal of the second inductor;
a third nMOS transistor having a drain coupled to a source of the first nMOS transistor and to a source of the second nMOS transistor; and
the biasing circuitry coupled to a gate of the third nMOS transistor for applying a gate bias.

26. The voltage controlled oscillator of claim 25 wherein the second cross-coupling stage comprises:
a first pMOS transistor having a gate connected to a first terminal of the third inductor; and
a second pMOS transistor having a gate connected to a second terminal of the third inductor;
a third pMOS transistor having a drain coupled to a source of the first pMOS transistor and to a source of the second pMOS transistor; and
the biasing circuitry coupled to a gate of the third pMOS transistor for applying a gate bias.

27. The voltage controlled oscillator of claim 24 wherein the biasing circuitry biases the first inductor, second inductor, third inductor separately such that noise associated with the first, second and third inductors are separated.

28. The voltage controlled oscillator of claim 26 wherein the biasing circuitry biases the third pMOS transistor and the third nMOS transistor separately such that noise associated with the third pMOS transistor and the third nMOS transistor are separated.
